(19) United States
(12) Patent Application Publication
(10) Pub. No.: US 2025/0349497 A1
(43) Pub. Date: Nov. 13, 2025

(54) METHOD FOR DESIGNING A MULTI-BEAM PARTICLE BEAM SYSTEM HAVING MONOLITHIC PATH TRAJECTORY CORRECTION PLATES, COMPUTER PROGRAM PRODUCT AND MULTI-BEAM PARTICLE BEAM SYSTEM

(71) Applicant: Carl Zeiss MultiSEM GmbH, Oberkochen (DE)

(72) Inventors: Dirk ZEIDLER, Oberkochen (DE); Thomas SCHMID, Aalen (DE); Sandra VOGEL, Ulm (DE)

(21) Appl. No.: 19/274,018

(22) Filed: Jul. 18, 2025

Related U.S. Application Data
(63) Continuation of application No. PCT/EP2024/025012, filed on Jan. 9, 2024.

(30) Foreign Application Priority Data
Jan. 25, 2023 (DE) 10 2023 101 774.8

(51) Int. Cl. H01J 37/147; G05B 17/02; H01J 37/145

(52) U.S. Cl. CPC H01J 37/1472; G05B 17/02; H01J 37/145

(57) ABSTRACT

A method for designing a multi-beam particle microscope and a multi-beam particle microscope operating with a multiplicity of charged individual particle beams and imaging the latter into an object plane and comprising a plurality of path trajectory correction plates are disclosed. Each of the path trajectory correction plates has a multiplicity of apertures for the multiplicity of individual particle beams and exactly one settable correction voltage is applied to each of the path trajectory correction plates during the operation of the multi-beam particle microscope. A path trajectory correction plate is fixedly assigned to an operating parameter of the multi-beam particle microscope. When designing the path trajectory correction plates, the apertures in the path trajectory correction plates are adapted in view of shape and size such that operating parameter-related path deviations of all individual particle beams can be corrected.

### CROSS-REFERENCE TO RELATED APPLICATIONS

The present application is a continuation of, and claims benefit under 35 USC 120 to, international application No. PCT/EP2024/025012, filed Jan. 9, 2024, which claims benefit under 35 USC 119 of German Application No. 10 2023 101 774.8, filed Jan. 25, 2023. The entire disclosure of each of these applications is incorporated by reference herein.

### FIELD

The disclosure relates to multi-beam particle beam systems in general multi-beam particle microscopes operating with a multiplicity of charged individual particle beams. For example, the disclosure relates to a method for designing a multi-beam particle beam system having monolithic path trajectory correction plates, to an associated computer program product and to a correspondingly designed multi-beam particle beam system.

### BACKGROUND

With the ongoing development of ever smaller and ever more complex microstructures such as semiconductor components, there is a desire to further develop and optimize planar production techniques and inspection systems for producing and inspecting small dimensions of the microstructures. By way of example, the development and production of the semiconductor components involve monitoring of the design of test wafers, and the planar production techniques involve process optimization for reliable production with high throughput. Moreover, there have been recent demands for an analysis of semiconductor wafers for reverse engineering and for a customized, individual configuration of semiconductor components. Therefore, there is a desire for an inspection mechanism which can be used with high throughput to examine the microstructures on wafers with high accuracy.

Typical silicon wafers used in the production of semiconductor components have diameters of up to 300 mm. Each wafer is usually divided into 30 to 60 repeating regions (“dies”) with a size of up to 800 mm². A semiconductor apparatus comprises a plurality of semiconductor structures, which are produced in layers on a surface of the wafer by planar integration techniques. Semiconductor wafers typically have a plane surface on account of the production processes. The structure dimension of the integrated semiconductor structures in this case extends from a few μm to the critical dimensions (CD) of a few nanometres, with the structure dimensions becoming even smaller in the near future. The expectation is that in future the structure dimensions or critical dimensions (CD) will correspond to the 3 nm, 2 nm or even smaller process nodes of the International Technology Roadmap for Semiconductors (ITRS). In the case of the aforementioned small structure dimensions, defects of the order of the critical dimensions are to be identified quickly over a very large area. For several applications, the desired accuracy of a measurement provided by inspection equipment is even higher, for example by a factor of two or one order of magnitude. By way of example, a width of a semiconductor feature are to be measured with an accuracy of below 1 nm, for example 0.3 nm or even less, and a relative position of semiconductor structures are to be determined with an overlay accuracy of below 1 nm, for example 0.3 nm or even less.

The MSEM, a multi-beam scanning electron microscope, is a relatively new development in the field of charged particle systems (charged particle microscopes, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a multiplicity of individual electron beams, which are arranged in a field or raster. By way of example, 4 to 10,000 individual electron beams can be provided as primary radiation, with each individual electron beam being separated from an adjacent individual electron beam by a pitch of 1 to 200 micrometres. By way of example, an MSEM has approximately 100 separate individual electron beams (“beamlets”), which are arranged for example in a hexagonal raster, with the individual electron beams being separated by a pitch of approximately 10 μm. The multiplicity of charged individual particle beams (primary beams) are focused on a surface of a sample to be examined by way of a common objective lens. By way of example, the sample can be a semiconductor wafer which is secured to a wafer holder mounted on a movable stage. When the wafer surface is illuminated by the charged primary individual particle beams, interaction products, for example secondary electrons or backscattered electrons, emanate from the surface of the wafer. Their start points correspond to those locations on the sample onto which the multiplicity of primary individual particle beams are focused in each case. The amount and the energy of the interaction products depend on the material composition and the topography of the wafer surface. The interaction products form a plurality of secondary individual particle beams (secondary beams), which are collected by the common objective lens and, by virtue of a projection imaging system of the multi-beam inspection system, are incident on a detector arranged in a detection plane. The detector comprises a plurality of detection regions, each of which comprises a plurality of detection pixels, and the detector captures an intensity distribution for each of the secondary individual particle beams. An image field of, for example, 100 μm×100 μm is obtained in the process.

A known multi-beam electron microscope comprises a sequence of electrostatic and magnetic elements. At least some of the electrostatic and magnetic elements are settable in order to adapt the focus position and the stigmation of the multiplicity of charged individual particle beams. Such a multi-beam charged particle system moreover comprises at least one cross-over plane of the primary or the secondary individual charged particle beams. Moreover, such a system comprises detection systems in order to facilitate the adjustment. Such a multi-beam particle microscope comprises at least one beam deflector (“deflection scanner”) for collective scanning of a region of the sample surface via the multiplicity of primary individual particle beams in order to obtain an image field of the sample surface.

What is known as a beam splitter (or alternatively beam separator or beam divider) is used to separate the particle-optical beam path of the primary beams from the particle-optical beam path of the secondary beams. In this case, separation is implemented via special arrangements of magnetic fields and/or electrostatic fields, for example via a Wien filter.

Imaging aberrations arise quite generally as a result of using particle-optical components. For example, these include field curvature and field astigmatism.

As the demands on the imaging quality increase, so do the demands on the multi-beam particle microscope used for imaging. For example, an object plane field curvature is minimized in order to obtain a very good resolution of a multi-beam particle microscope. In a first measure, the electron-optical unit or the charged particle-optical unit of the multi-beam particle microscope is optimized. However, these measures have their limit on account of the Scherzer theorem. However, this limit does not suffice for the current desired beam uniformity.

Therefore, it has been proposed to use active apparatuses for an individual focal length adaptation for each beam, for example arrays of individually addressable ring electrodes as active parts of micro-individual-lens arrays. The focal length of an individual micro-individual-lens has an approximate quadratic dependence on the voltage applied to the respective lens electrode. However, these active apparatuses for correcting the field curvature for each individual particle beam can be hard to manufacture and expensive. It can be desirable here that each individual micro-correction-apparatus functions perfectly because otherwise this type of correction apparatus does not make sense. Moreover, it can be for example challenging to supply each micro-individual-lens arrangement with a voltage of the order of more than 50 V, more than 100 V or even more than 400 V. This is because considerable insulation issued can arise in the process, and the current active correction apparatuses might have only a very limited service life. Examples of active correction apparatuses are found e.g. in U.S. Pat. Nos. 5,834,783, 6,483,120, 6,903,353, 7,126,141 and 11,145,485.

An alternative approach proposes the use of passive apparatuses, e.g. arrays of monolithic individual lens systems, with only a single control voltage being provided for the entire array. It is known that the focal length of an individual lens is approximately proportional to the diameter of the opening in the central electrode of the individual lens. Thus, an individual focal length variation can also be obtained for each individual particle beam by suitably varying the diameters of the openings in a plate with a plurality of openings, which is a part of the individual lens arrangement. Thus, the field curvature and also a field inclination can be corrected by applying a single control voltage to the multi-aperture plate with different hole diameters. Examples of such passive correction apparatuses are found e.g. in JP60105229, U.S. Pat. Nos. 10,504,681, 10,784,070 and 11,139,138. Further examples are disclosed in U.S. Pat. No. 10,923,313 B1 and U.S. Pat. No. 11,322,335 B2.

It is also known to correct a field astigmatism via a monolithic multi-aperture plate. U.S. Pat. No. 7,554,094 B2 discloses elliptical apertures whose semi-major axis increases as the distance from a central aperture or a centre increases, wherein an orientation of the semi-major axis is orthogonal to a longitudinal axis of elliptical beam spots that would be formed in an object plane if there were no appropriate correction.

U.S. Pat. No. 10,923,313 B1 discloses monolithic multi-aperture plates, to which exactly one voltage is applied in each case and which have either circular apertures with different sizes or elliptical apertures with different sizes. In the case of the elliptical apertures, a ratio Q of semi-major axis to semi-minor axis scales with the distance r from a central aperture in the plate (radial variation) or else in the x or y direction (Cartesian variation). To correct an imaging aberration with great accuracy, it is proposed to use a multiplicity of monolithic multi-aperture plates, which emulate the terms of a polynomial providing a series expansion of imaging aberrations or their correction. For example, a plurality of successive plates, each with an individual scaling of the aperture diameters in each plate, e.g. according to r in a first plate, according to r² in a second plate, according to r³ in a third plate, according to r⁴ in a fourth plate, etc., correct e.g. a field curvature, or a plurality of successive plates, each with an individual scaling of the ratio Q on each plate, correct e.g. a field astigmatism. The more accurate a correction of aberrations is intended to be, in general, the more monolithic multi-aperture plates are used for the correction. US 2011/0147605 A1 discloses, for the purpose of correcting aberrations, a plurality of plate sequences each having an opening with a specific geometry, whereby one multi-pole field is generated, respectively. Specifically, US 2011/0147605 A1 describes by way of example a hexapole corrector for correcting a spherical aberration. This aberration is rotationally symmetrical. In connection with multiple particle beam systems, US 2011/0147605 A1 discloses a system having a plurality of tips (“emitter tips”) for generating a multiplicity of particle beams. The generated multiplicity of particle beams respectively pass through sequences of a plurality of multi-aperture plates each having a plurality of openings with a specific geometry. In that case, a (global) voltage is applied to each multi-aperture plate. An identical aberration correction for all the particle beams can be realized as a result. Field profiles or a field-dependent individual aberration correction are not addressed in US 2011/0147605 A1, nor are they possible with the subject matter in US 2011/0147605 A1.

### SUMMARY

The disclosure seeks to improve and/or simplify the correction of aberrations in multi-beam particle beam systems and, for example, multi-beam particle microscopes. The implementation of the correction can be precise and elegant. The correction elements can be simple to produce and/or simple to integrate in multi-beam particle beam systems.

The present disclosure uses monolithic multi-aperture plates as correction elements for aberrations, similar to certain known systems. However, with regards to the design of the monolithic multi-aperture plates or path trajectory correction plates, there is a change of strategy in several respects.

In certain known monolithic multi-aperture plates, following their production, there is only one free parameter that can be varied for the purpose of correcting aberrations, specifically the voltage applied to the respective plate. The parameter varied within the existing monolithic multi-aperture plates is likewise only a single parameter, specifically the aperture size. In this case, the shape of the aperture is fixed. The present disclosure departs from this stipulation. According to the disclosure, it is not only the size of the apertures in a plate that is varied in the context of designing a monolithic multi-aperture plate or path trajectory correction plate but also the respective shape of the apertures. Thus, within the scope of a design process, there are at least two freely selectable parameters for each aperture in the plate and not only a single parameter.

Moreover, there is a sort of basis change shift according to the disclosure: Rather than providing a plate, or rather a sequence of plates, for correcting a specific category of imaging aberration (field curvature or astigmatism correction or image plane tilt, etc.), the monolithic multi-aperture plates are designed according to the disclosure for the purpose of correcting imaging aberrations when specific operating parameters are modified. Thus, the plates to be designed are adapted specifically to the respective multi-beam particle beam system. This can help allow relatively good aberration corrections with fewer and possibly markedly fewer monolithic multi-aperture plates overall.

Specifically, according to a first aspect, the disclosure relates to a method for designing a multi-beam particle beam system, for example a multi-beam particle microscope, operating with a multiplicity of charged individual particle beams and imaging the latter into an object plane and comprising a plurality of path trajectory correction plates, wherein each of the path trajectory correction plates has a multiplicity of apertures for the multiplicity of individual particle beams and wherein exactly one settable correction voltage for generating a contribution to the path correction is applied to each of the path trajectory correction plates during the operation of the multi-beam particle beam system, wherein the method includes the following steps:
defining operating parameters which describe an operating state of the multi-beam particle beam system;
defining operating parameter intervals for each operating parameter, included in which are possible values for the respective operating parameter during an operation of the multi-beam particle beam system;
determining an individual particle beam path deviation from an ideal individual particle beam path for each operating parameter along its operating parameter interval for each of the individual particle beams; and
designing the path trajectory correction plates,
wherein each operating parameter is assigned a path trajectory correction plate, and
wherein the sizes of the apertures are determined for each path trajectory correction plate on the basis of the respective determined path deviations of the associated individual particle beams along the operating parameter interval, and
wherein the shapes of the respective apertures are determined for each path trajectory correction plate on the basis of the respective determined path deviations of the associated individual particle beams along the operating parameter interval,
with the result that path deviations occurring on account of changes of an operating parameter within its operating parameter interval can be corrected by applying exactly one correction voltage to the path trajectory correction plate assigned to this operating parameter.

Within the scope of this patent application, the terms path trajectory correction plate on the one hand and monolithic multi-aperture plate on the other hand are used synonymously. There are at least two path trajectory correction plates. However, more path trajectory correction plates may be provided, for example three, four, five, six, seven, eight, nine or ten path trajectory correction plates. Optionally, there are less than ten path trajectory correction plates, such as five path trajectory correction plates or fewer. In this case, the number of apertures per path trajectory correction plate is matched to the number of individual particle beams in the multi-beam particle beam system to be designed. In this case, the path trajectory correction plates are provided in succession in the particle-optical beam path. However, they need not be provided directly in succession but their position may be varied and optimized within the scope of the design process. Certain positions of path trajectory correction plates will still be discussed below.

The operating parameters describe an operating state of the multi-beam particle beam system. The scope of defining the operating parameters does not necessarily mean that all operating parameters that describe an operating state of the multi-beam particle beam system are in fact defined within the scope of the method according to the disclosure. Rather, this relates to the selection of operating parameters whose change causes an influence or noticeable influence on path deviations of the individual particle beams from the ideal particle beam paths. At least two operating parameters are defined. However, it is naturally also possible to define three, four or more operating parameters. For example, examples of operating parameters include the beam current, the landing energy and the beam pitch of the individual particle beams. Further examples will be mentioned below.

The definition of operating parameter intervals for each operating parameter defines the limits within which an operating parameter may change or should change during the operation of the multi-beam particle beam system. In this context, it is not necessary for the operating parameters to be continuously changeable within the intervals. Rather, the intention is that all values which the operating parameters can adopt during the operation of the multi-beam particle beam system, for example which are accordingly settable by a user, are also covered by the operating parameter intervals.

According to the disclosure, an individual particle beam path deviation from an ideal individual particle beam path can be determined along its operating parameter interval for each of the individual particle beams. By way of example, this path deviation can be determined by an appropriate particle-optical simulation. However, it is also possible for corresponding measurements to be made on a multi-beam particle beam system that is intended to be designed. In this case, the path deviations of the individual particle beams can be determined relative to a reference position in the particle-optical beam path, typically at the incidence of the individual particle beams in an object plane. However, it is also conceivable for a different plane in the particle-optical beam path to be chosen as reference position or reference plane, for example upstream of those particle-optical elements involving an exact passage of the individual particle beams, for example delicate multi-beam deflectors. By way of example, the ideal individual particle beam path can be chosen such that a diameter of the individual particle beam upon incidence in an object plane is minimal. That is to say, the object plane passes precisely through the beam waist. In addition or in an alternative, an ideal individual particle path can be chosen such that the beam diameter is perfectly round or stigmatic. According to the disclosure, the path deviation can be determined for each individual particle beam, to be precise for each operating parameter along its operating parameter interval. The scope of this determination thus can include the operating parameter being varied. At least two values of an operating parameter are measured or simulated, but it is also possible for the entire operating parameter interval to be traversed, so to speak. It should be emphasized again at this juncture that the path deviations of the individual particle beams in this type of fine correction according to the disclosure have a field profile. Global corrections, i.e. corrections used equally for all individual particle beams, need not be corrected via the monolithic multi-aperture plates or path trajectory correction plates. They may be corrected beforehand via global corrections.

According to the disclosure, designing the path trajectory correction plates includes assigning a path trajectory correction plate to each operating parameter. Optionally, each operating parameter is assigned exactly one path trajectory correction plate, and hence there is a 1:1 mapping. However, it is also possible that an operating parameter is assigned two path trajectory correction plates, for example if it is not possible within one path trajectory correction plate to correct the path deviations caused when this operating parameter changes. However, this is hardly ever the case. In most cases, an operating parameter change involves a path correction which is largely independent from the respective current setting of other operating parameters. This can contribute to reducing the overall number of path trajectory corrections used in the system. In some cases, it is even possible to encode a plurality of operating parameters in only one path trajectory correction plate. But even in the case where the operating parameters are not independent of one another, in the sense that the path corrections rendered desirable thereby are not independent of one another, solving a multi-dimensional optimization problem nevertheless renders it possible to determine a basis set of path trajectory correction plates, which covers the entire possible state space of the multi-beam particle beam system and in which the number of path trajectory correction plates is minimized at the same time.

According to the disclosure, it is not only the size of the apertures but also the shape of the respective apertures that can be varied when the path trajectory correction plates are designed. Thus, in general, a task is that of finding the aperture which provides the best implementation of the desired path correction for the respective individual particle beam along the operating parameter interval. In this case, the value of the operating parameter can be reflected by the voltage applied to the path trajectory correction plate.

The terms size and shape can be defined in different ways. The definition is naturally simple in the case of circular apertures. For example, the size can be specified as the diameter of the aperture, the shape itself as circular. However, even in the case of an elliptical or oval aperture, the size of the aperture and the shape of the aperture can be defined in respectively different ways. Reference to the semi-major axis of an ellipse, to a semi-minor axis of the ellipse, to a ratio of semi-major axis to semi-minor axis or else to the overall area of the opening is possible. There are even more options for the definition of size and shape in the case of shapes of three-fold or four-fold symmetry shapes. However, these definitions are not really decisive within the patent application. As mentioned above, a task is that of determining the ideal aperture. In general, this means the greatest possible freedom when finding the aperture. Thus, there is more than one degree of freedom for the definition of the aperture. This is a difference relative to certain known systems. At this juncture, reference is also made once again to the fact that a circular aperture, through which a central individual particle beam in the field of the plurality of individual particle beams passes, normally does not have a different shape to for example an otherwise elliptical field of apertures. In this context, the circle is only a special case of the ellipse and inserted mathematically exactly into the field profile of the shapes or ellipses. It is not as if there were a plurality of free parameters for choosing the aperture in the case of this type of multi-aperture plate.

The procedure when determining the size and shape of the respective apertures can be that, for example, two or more parameters for describing the aperture are defined and subsequently varied and optimized. Finally, the optimal apertures are then determined for each individual particle beam and designing the path trajectory correction plate is thus completed. As a result, a fully designed path trajectory correction plate may comprise apertures of different sizes and different shapes. However, it is also possible that there is in fact only a variation in the size of the apertures in the path trajectory correction plate because it turned out that there was no need to vary the shape. However, the shape of the apertures in the plate was not defined from the outset within the design process itself. Instead, the shape was permitted to vary as a general matter. Ultimately, the shape depends on the operating parameter itself and its influence on path deviations of the individual particle beams.

According to an embodiment of the disclosure, the orientation of the shape within the path trajectory correction plate is also determined when determining the shape of an aperture. This is practical, for example, in the case of strictly geometric shapes, for example if the orientation of a semi-major axis of an ellipse is specified.

According to an embodiment of the disclosure, the scope of determining the size of the respective aperture via a simulation includes the determination of a relationship between the size of the aperture and a focus shift caused thereby when a correction voltage is applied to the path trajectory correction plate; and/or the scope of determining the shape of the respective aperture via a simulation includes the determination of a relationship between the shape of the aperture and a modified beam profile caused thereby when a correction voltage is applied to the path trajectory correction plate. Conventional particle-optical simulation programs can be used for the simulation. The modified beam profile for example describes the deviation of the beam profile from the ideal beam profile, for example a stigmatic beam profile.

According to an embodiment of the disclosure, there is a repeat determination of a relationship between the size of the aperture and a focus shift caused thereby when at least one further correction voltage is applied; and/or there is a repeat determination of a relationship between the shape of the aperture and a modified beam profile caused thereby when at least one further correction voltage is applied. As a result, the operating parameter interval can be covered point by point or traversed within the scope of a simulation. In this case, the correction for a specific operating parameter is always implemented or simulated by applying a correction voltage.

According to an embodiment of the disclosure, the applied correction voltages cover or correct path deviations substantially over the entire operating parameter interval of the path trajectory correction plate associated with this operating parameter, wherein the following are determined. A best fit at all applied correction voltages for the size of the aperture and a best fit for the shape of the aperture for the individual particle beam passing through this aperture. In this case, it is possible for the best fit to be determined at the same time for both the size of the aperture and the shape of the aperture. Ultimately, this depends on the mathematical or algorithmic implementation of the variations in a simulation program.

According to an embodiment of the disclosure, the designing of a path trajectory correction plate comprises an optimization of the individual particle beam profiles to the most stigmatic beam profile possible downstream of the path trajectory correction. This is the standard case. However, in general, a different beam profile could also be chosen as optimal beam profile. Ultimately, this depends on the experiment carried out with the multi-beam particle beam system.

According to an embodiment of the disclosure, one or more apertures in a path trajectory correction plate have the shape of at least one of the shapes listed hereinafter: a circle, an ellipse, a shape with a two-fold symmetry, a shape with a three-fold symmetry, a shape with a four-fold symmetry, a shape with a five-fold symmetry, a shape with a six-fold symmetry, a shape with a seven-fold symmetry, a shape with an eight-fold symmetry. Shapes with general n-fold symmetry are n-gons with n≥2 and n∈N. Here, these regular n-gons may be rounded off since points can be undesirable when forming electrodes which are ultimately represented by the apertures. A shape with three-fold symmetry can for example be an equilateral triangle with rounded-off corners, a shape with four-fold symmetry can for example be a square shape with rounded-off corners, etc. However, other shapes with n-fold symmetry which are not n-gons are naturally also possible.

According to an embodiment of the disclosure, one or more apertures in a path trajectory correction plate have a free-form shape as a shape. Thus, the aperture or the apertures may be shaped entirely irregularly. An aperture is formed precisely in the manner optimal for the path trajectory correction. When designing the apertures in a path trajectory correction plate, it is relevant to find the apertures such that the corrections caused thereby fit precisely to the present system.

According to an embodiment of the disclosure, the operating parameters comprise such parameters or consist of such parameters which can be selected by a user of the multi-beam particle beam system for the operation of the multi-beam particle beam system. Thus, the user has direct access to these parameters. Typically, these parameters are the parameters set by the user in order to suitably carry out an experiment to be carried out by him or a measurement to be carried out by him.

According to an embodiment of the disclosure, the operating parameters comprise at least one parameter from the list of: beam current, landing energy, pitch of the individual particle beams upon incidence in an object plane, angle upon incidence of the individual particle beams in an object plane (telecentricity). In this case, the beam current can be varied, for example by adjusting a condenser lens system (fanning the illuminating beam prior to its incidence on a multi-beam generator). In addition or in an alternative, a tip can be operated differently. By way of example, a landing energy variation can be realized by virtue of a variable voltage being applied to a sample holder, thus generating a deceleration field for primary electrons or charged first individual particle beams or generating a suction field for secondary electrons or second individual particle beams. A pitch of the individual particle beams upon incidence in an object plane is linked to the magnification of the system and can be modified for example via a setting of the objective lens and/or a variation in the working distance. An angle upon incidence of the individual particle beams in an object plane can be varied or corrected for example by a corrector arranged in an intermediate image, if this relates to a telecentric incidence of the individual particle beams. A telecentric incidence of the individual particle beams on a sample is desirable in many practical applications.

According to an embodiment of the disclosure, the operating parameters comprise such parameters or consist of such parameters which are component-related manipulation parameters. Optionally, the component-related manipulation parameters are not parameters which can be selected by a user of the multi-beam particle beam system for the operation of the multi-beam particle beam system.

According to an embodiment of the disclosure, the manipulation parameters comprise at least one parameter from the list of parameters listed hereinafter: beam splitter excitation, objective lens excitation, field lens excitation. The excitation can be a voltage and/or a current in each case. Ultimately, this depends on the structural design of the particle optics. According to this embodiment of the disclosure, it is thus possible to undertake corrections of path trajectories in component-related fashion. For example, in that case there is a path trajectory correction plate for the beam splitter, a path trajectory correction plate for the objective lens and a path trajectory correction plate for a field lens, etc.

According to an embodiment of the disclosure, an operating parameter is assigned exactly one path trajectory correction plate. This can contribute to keeping the overall number of path trajectory correction plates small.

According to an embodiment of the disclosure, the method moreover includes the following step: minimizing the number of path trajectory correction plates involved. It is within the realm of possibility that all states of the multi-beam particle beam system can already be mapped or corrected with fewer than the originally determined or designed path trajectory correction plates. The minimization of the number of path trajectory correction plates involved then actually is an orthogonalization of the employed path trajectory correction plate system. However, whether this is possible depends individually on the multi-beam particle beam system to be designed and for example also on the intended or desired quality of a path trajectory correction for a specific measurement or inspection. Under certain circumstances, it is possible to obtain a simplified system with fewer path trajectory correction plates by way of a skillful combination and a certain tolerance with regards to the residual error.

According to an embodiment of the disclosure, a number of all operating parameters of the multi-beam particle beam system is greater than the number of all path trajectory correction plates in the system. By way of example, this might be an orthogonalized path trajectory correction plate system in this case.

According to an embodiment of the disclosure, the method moreover includes selecting a base set of path trajectory correction plates which provide a path trajectory correction for all path corrections to be expected in the system to be designed. This is a multi-dimensional optimization. A person skilled in the art knows how to implement the latter in general, for example using optimization methods and/or recursive methods, etc. A further optimization goal that could also be sought after within the scope of the optimization is that of minimizing the overall number of path trajectory correction plates to be designed with a maximally admissible residual error tolerance. More path trajectory correction plates tend to be used for the path trajectory correction if an acceptable residual error is very small; if an acceptable residual error is slightly larger, then it may be possible to make do with fewer path trajectory correction plates for the path trajectory correction. Moreover, a skillful choice of the basis as a linear combination of path trajectory corrections renders it possible to reduce the number of path trajectory correction plates involved.

According to a second aspect, the disclosure relates to a computer program product having a program code for carrying out the method as described above in various embodiments. In this context, the program code can be written in any programming language. In this context, the program code may have a modular structure. By way of example, a module may resort to input and/or output parameters of a particle-optical simulation program.

According to a third aspect, the disclosure relates to a multi-beam particle beam system, for example a multi-beam particle microscope, designed via the method as described above in a plurality of embodiments. Typically, such a multi-beam particle beam system will comprise at least one path trajectory correction plate with apertures, which have both different sizes and different shapes. However, this need not be the case.

According to a fourth aspect, the disclosure relates to a multi-beam particle microscope, having the following features:
a multi-beam generator configured to generate a first field of a multiplicity of charged first individual particle beams;
a first particle-optical unit with a first particle-optical beam path, configured to image the generated first individual particle beams onto a sample surface in the object plane such that the first individual particle beams are incident on the sample surface at incidence locations, which form a second field;
a detection system with a multiplicity of detection regions which form a third field;
a second particle-optical unit with a second particle-optical beam path, configured to image second individual particle beams, which emanate from the incidence locations in the second field, onto the third field of the detection regions of the detection system;
a magnetic and/or electrostatic objective lens, through which both the first and the second individual particle beams pass;
a beam splitter, which is arranged in the first particle-optical beam path between the multi-beam generator and the objective lens and which is arranged in the second particle-optical beam path between the objective lens and the detection system;
a plurality of path trajectory correction plates each with a multiplicity of apertures which are passed by the multiplicity of first individual particle beams during operation and to which exactly one correction voltage assigned to the path trajectory correction plate is applied during operation; and
a controller,
wherein apertures of different sizes and different shapes are arranged in at least one of the path trajectory correction plates, and
wherein the controller is configured to control the plurality of path trajectory correction plates during operation with a correction voltage which is individually predefined for each path trajectory correction plate, wherein the respective correction voltages are selected by the controller on the basis of operating parameters for the multi-beam particle microscope.

The first individual charged particle beams can be, for example, electrons, positrons, muons or ions or other charged particles. It is desirable if the number of first individual particle beams is 3n(n−1)+1, where n is any natural number. The first individual particle beams can then be arranged in a hexagonal field. However, other arrangements of the first individual particle beams are also possible. The second individual particle beams can be backscattered electrons or else secondary electrons. In this case, for analysis purposes, the low-energy secondary electrons can be used for image generation. However, it is also possible for mirror ions/mirror electrons to be used as second individual particle beams, which is to say first individual particle beams undergoing reversal directly upstream of the object or at the object.

In this case, the controller of the multi-beam particle microscope can be formed in one part or in multiple parts. For example, it is possible that the controller comprises a specific module for controlling the path trajectory correction plates. However, this need not be the case.

According to an embodiment of the disclosure, one of the path trajectory correction plates is adapted to undertake a path trajectory correction on the basis of a beam current or a beam current change. Such a path trajectory correction plate thus corresponds to a beam current correction plate. If there is a change in the beam current then there is a change in the path trajectory correction plate control.

In addition or in an alternative, one of the path trajectory correction plates is adapted to undertake a path trajectory correction on the basis of a landing energy or a change in the landing energy. This corresponds to a landing energy correction plate.

In addition or in an alternative, one path trajectory correction plate is adapted to undertake a path trajectory correction on the basis of a pitch or a change in pitch of the first individual particle beams upon incidence of the first individual particle beams in the object plane. This path trajectory correction plate thus corresponds to a pitch correction plate.

In addition or in an alternative, one of the path trajectory correction plates is adapted to undertake a path trajectory correction on the basis of the angle or a change in angle of the first individual particle beams upon incidence of the first individual particle beams in the object plane. This path trajectory correction plate hence corresponds to a telecentricity correction plate.

The path trajectory correction plates mentioned by way of example in accordance with this embodiment variant can be typical path trajectory correction plates of operating parameters which can be actively selected by a user of the multi-beam particle microscope for the operation of the multi-beam particle microscope.

According to an embodiment of the disclosure, one of the path trajectory correction plates is adapted to undertake a path trajectory correction on the basis of an excitation or an excitation change of the objective lens. This path trajectory correction plate hence corresponds to an objective lens correction plate.

In addition or in an alternative, one of the path trajectory correction plates is adapted to undertake a path trajectory correction on the basis of an excitation or an excitation change of the beam splitter. This type of path trajectory correction plate corresponds to a beam splitter correction plate.

In addition or in an alternative, one of the path trajectory correction plates is adapted to undertake a path trajectory correction on the basis of an excitation or an excitation change of a field lens arranged in the first particle-optical beam path. Such a path trajectory correction plate corresponds to a field lens correction plate.

The path trajectory correction plates described in this embodiment can be typical examples of component-related path trajectory correction plates. However, the component relationship says nothing about the specific arrangement of the path trajectory correction plates in the particle-optical beam path. Instead, type of path trajectory correction to be carried out via the corresponding path trajectory correction plate in relation to the type of aberration correction is decisive. The arrangement of the corresponding path trajectory correction plates in the beam path depends thereon.

According to an embodiment of the disclosure, the multi-beam generator comprises at least one path trajectory correction plate; and/or a path trajectory correction plate is arranged in the region of an intermediate image plane.

In any case, the multi-beam generator may comprise a stack of multi-aperture plates which firstly generate the multiplicity of first individual particle beams in the first place and secondly also carry out first corrections on the individual particle beams. By way of example, the focus shift or the field curvature can be pre-corrected as a general matter. The same applies to a field astigmatism. In an alternative or in addition, the path trajectory correction plates according to the disclosure may be provided in the multi-beam generator. The multiplicity of individual particle beams are strictly separated from one another in the region of the multi-beam generator. Nevertheless, the beam waist of the individual particle beams is not minimal in the region of the multi-beam generator but has a certain extent. In general, path trajectory correction plates arranged in the region of the multi-beam generator can then compensate any field dependence of an aberration.

If a path trajectory correction plate is arranged in the region of an intermediate image plane, then the beam diameter of the individual particle beams is at a minimum there.

Only the angle of each individual particle beam can be influenced individually via a path trajectory correction plate at such a location. Thus, a telecentricity correction plate could for example be arranged in the region of an intermediate image.

According to an embodiment of the disclosure, a respective multi-aperture plate with a multiplicity of round apertures is arranged directly upstream and directly downstream of a path trajectory correction plate, wherein the same voltage, for example earth potential, is applied to the two multi-aperture plates. This allows a better separation of the field profiles generated by the path trajectory correction plates. For example, it is possible to provide an alternating sequence of path trajectory correction plates on the one hand and earthed multi-aperture plates on the other hand in the multi-beam generator. This arrangement has a particularly simple structure.

According to an embodiment of the disclosure, the multi-beam particle microscope moreover comprises a mechanism for in-situ plasma cleaning of the path trajectory correction plates; and/or the multi-beam particle microscope comprises a mechanism for providing a low partial pressure of hydrogen gas during an operation of the multi-beam particle microscope for cleaning purposes. The hydrogen can be provided continuously during the operation of the multi-beam particle microscope or it can be provided in pulsed form or intermittently between various recordings or, in general terms, during an interruption of an image recording—or interruption of a scanning procedure. In addition or in an alternative, the multi-beam particle microscope may comprise a mechanism for continually heating the path trajectory correction plates. Heating contributes to the cleaning of the path trajectory correction plates. Cleaning the path trajectory correction plates is desirable for a correct functionality of the path trajectory correction plates or for a precise correction of the path trajectories since contaminations or deposits on the apertures in the path trajectory correction plates may impair the highly precise correction.

According to an embodiment of the disclosure, the multi-beam particle microscope comprises at least one further path trajectory correction plate in the second particle-optical beam path in addition or in an alternative to the path trajectory correction plates in the first particle-optical beam path, wherein the further path trajectory correction plate has a multiplicity of apertures, through which the multiplicity of second individual particle beams pass during operation and to which exactly one correction voltage assigned to the further path trajectory correction plate is applied during operation, wherein apertures of different sizes and different shapes are arranged in the at least one path trajectory correction plate, and wherein the controller is configured to control the path trajectory correction plate during operation with a further correction voltage which is individually predefined for the further path trajectory correction plate, wherein the further correction voltage is selected by the controller on the basis of an operating parameter for the multi-beam particle microscope.

A design of the apertures in the further path trajectory correction plate in the second particle-optical beam path can be implemented in a manner analogous to the above-described method for designing the multi-beam particle beam system with monolithic path trajectory correction plates in the first particle-optical beam path.

The above-described aspects and embodiments of the disclosure can be combined with one another in full or in part, provided that no technical contradictions arise as a result.

### BRIEF DESCRIPTION OF THE DRAWINGS

In the figures:

FIG. 1: schematically shows a multi-beam particle microscope;

FIGS. 2A-2C: show a plurality of monolithic multi-aperture plates with openings of the same shape;

FIGS. 3A-3C: schematically illustrates apertures in different shapes;

FIG. 4: illustrates, in the form of a flowchart, a method according to the disclosure for designing a multi-beam particle beam system;

FIG. 5: schematically shows a path trajectory correction plate for a beam splitter;

FIG. 6: schematically shows a path trajectory correction plate for an objective lens;

FIG. 7: schematically shows an alternative path trajectory correction plate for an objective lens;

FIG. 8: schematically shows a path trajectory correction plate with three-fold apertures of different shapes;

FIG. 9: schematically shows a path trajectory correction plate with four-fold apertures of different shapes;

FIG. 10: schematically shows a path trajectory correction plate with free-form apertures;

FIG. 11: schematically illustrates the ratio S of individual beam diameter to beam bundle diameter;

FIG. 12: schematically shows a multi-beam particle microscope with path trajectory correction plates, designed in accordance with the method according to the disclosure;

FIG. 13: schematically shows a multi-beam generator with monolithic path trajectory correction plates;

FIG. 14: schematically shows a multi-beam generator with monolithic path trajectory correction plates.

### DETAILED DESCRIPTION

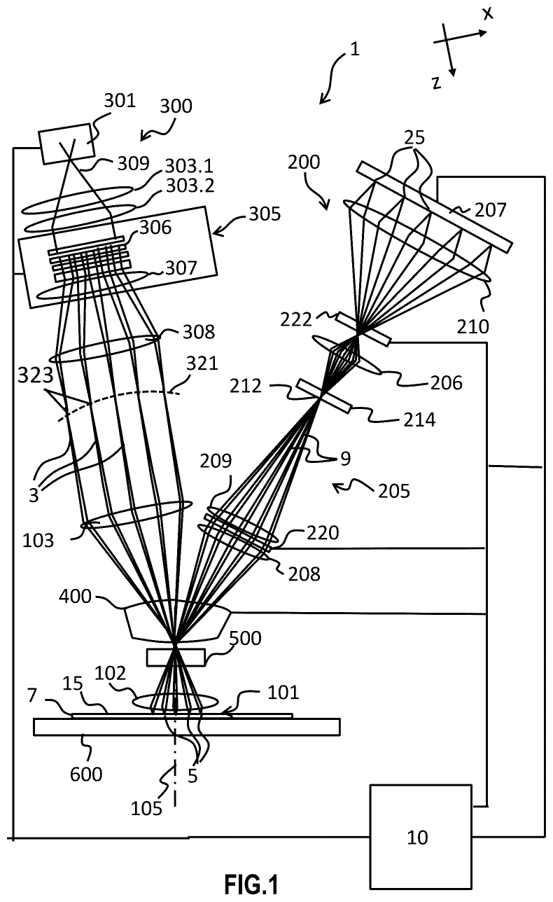

FIG. 1 schematically shows a multi-beam particle microscope 1. The multi-beam particle microscope 1 comprises a beam generating apparatus 300 with a particle source 301, for example an electron source. A divergent particle beam 309 is collimated by a sequence of condenser lenses 303.1 and 303.2, and impinges on a multi-aperture arrangement 305. The multi-aperture arrangement 305 comprises a plurality of multi-aperture plates 306 and a field lens 308. A multiplicity of individual particle beams 3 or individual electron beams 3 is generated by the multi-aperture arrangement. Midpoints of apertures in the multi-aperture plate arrangement are arranged in a field which is imaged onto a further field formed by beam spots 5 in the object plane 101. The distance between the midpoints of apertures of a multi-aperture plate 306 can be 5 μm, 100 μm and 200 μm, for example. The diameters D of the apertures are smaller than the pitch of the midpoints of the apertures; examples of the diameters are 0.2 times, 0.4 times and 0.8 times the distances between the midpoints of the apertures.

The multi-aperture arrangement 305 and the field lens 308 are configured to generate a multiplicity of focal points 323 of primary beams 3 in a raster arrangement on a surface 321. The surface 321 need not be a plane surface but rather can be a spherically curved surface in order to account for a field curvature of the subsequent particle-optical system.

The multi-beam particle microscope 1 further comprises a system of electromagnetic lenses 103 and an objective lens 102, which image the beam foci 323 from the intermediate image surface 325 into the object plane 101 with reduced size. In between, the first individual particle beams 3 pass through the beam splitter 400 and a collective beam deflection system 500, via which the multiplicity of first individual particle beams 3 are deflected during operation and the image field is scanned. The first individual particle beams 3 incident in the object plane 101 for example form a substantially regular field, wherein distances between adjacent incidence locations 5 can be 1 μm, 10 μm or 40 μm, for example. By way of example, the field formed by the incidence locations 5 can have a rectangular or hexagonal symmetry.

The object 7 to be examined can be of any desired type, for example a semiconductor wafer or a biological sample, and can comprise an arrangement of miniaturized elements or the like. The surface 15 of the object 7 is arranged in the object plane 101 of the objective lens 102. The objective lens 102 can comprise one or more electron-optical lenses. By way of example, this can be a magnetic objective lens and/or an electrostatic objective lens.

The primary particles 3 incident on the object 7 generate interaction products, for example secondary electrons, backscattered electrons or primary particles which have experienced a reversal of movement for other reasons, and these interaction products emanate from the surface of the object 7 or from the first plane 101 or object plane 101. The interaction products emanating from the surface 15 of the object 7 are shaped by the objective lens 102 to form secondary particle beams 9. In the process, the secondary beams 9 pass through the beam splitter 400 downstream of the objective lens 102 and are supplied to a projection system 200. The projection system 200 comprises an imaging system 205 with projection lenses 208, 209 and 210, a contrast stop 214 and a multi-particle detector 207. Incidence locations 25 of the second individual particle beams 9 on detection regions of the multi-particle detector 207 are located with a regular pitch in a third field. Exemplary values are 10 μm, 100 μm and 200 μm.

The multi-beam particle microscope 1 furthermore has a computer system or control unit 10, which in turn can be embodied in one part or in multiple parts and which is designed both to control the individual particle-optical components of the multi-beam particle microscope 1 and to evaluate and analyse the signals obtained by the multi-detector 207 or detection unit.

Further information relating to such multi-beam particle beam systems or multi-beam particle microscopes 1 and components used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is incorporated in full in the present application by reference.

As a result of using particle-optical components, imaging aberrations occur as a general matter in the illustrated multi-beam particle microscope 1. For this reason, the electron optics or generally the optics for charged particles of the multi-beam particle microscope 1 is optimized. However, these measures have their limit on account of the Scherzer theorem and are no longer sufficient for the current desired beam uniformity. The illustrated multi-beam particle microscope 1 may therefore comprise one or more correction mechanisms. For example, these correction mechanisms may include monolithic multi-aperture plates with apertures of a given shape but with different sizes over the field profile; these are known per se. In addition or in an alternative, the path trajectory correction plates 350 (not depicted in FIG. 1) according to the disclosure can also be arranged at different positions in the particle-optical beam path in the multi-beam particle microscope 1 as correction mechanisms. These path trajectory correction plates 350 are designed in accordance with the method according to the disclosure. This will be explained in detail hereinbelow.

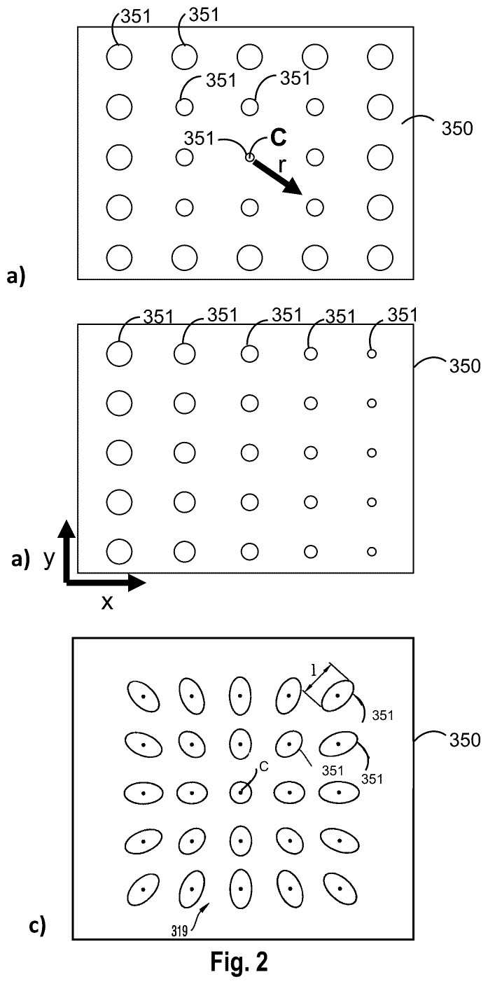

FIGS. 2A-C schematically show a plurality of monolithic multi-aperture plates 350 with openings 351. In this case, the openings 351 in the respective plate 350 in general have the same shape: The example according to FIG. 2A depicts a monolithic multi-aperture plate 350 whose apertures 351 are all circular. However, the size of the apertures 351 differs depending on the position of the respective apertures 351 in the field of apertures 351. In the example shown, a diameter of the apertures 351 increases with radial distance r from a midpoint C in the monolithic multi-aperture plate 350. Thus there is a radial dependence on the aperture size; it varies as a function of r. In this case, the dependence on r may differ, e.g. be linear, quadratic, cubic, hyperbolic, etc.

FIG. 2B shows a monolithic multi-aperture plate 350 with circular apertures 351 which exhibit a Cartesian variation in the diameter along the Cartesian coordinate x. The diameters of the apertures 351 do not vary in the direction of the Cartesian coordinate y. For example, a field tilt can be corrected via such a multi-aperture plate 350. Naturally, a variation of the aperture diameters in the y-direction could also be impressed upon a multi-aperture plate 350 while no variation in the aperture diameter is provided for along the x-coordinate. It is also possible to implement a variation both in the x-direction and in the y-direction (i.e., obliquely) in a multi-aperture plate 350.

FIG. 2C shows a monolithic multi-aperture plate 350 with elliptical apertures 351 (the aperture around the midpoint C positioned centrally in the plate 350 is only a special case of the ellipse here and not a different shape). The longitudinal axis 1 of the elliptical apertures 351 grows with distance from the midpoint C. Such a monolithic multi-aperture plate 350 can be used to correct a field astigmatism. The orientation of the longitudinal axis 1 in relation to the midpoint 358 then is transverse to an orientation of the longitudinal axis of astigmatic beam spots upon incidence in an object plane (not depicted here). In the example shown, the orientation of the longitudinal axis 1 is variable in Cartesian coordinates within the field of apertures; at the same time, its orientation is fixedly specified, to be precise in the radial direction from the midpoint C. Thus, the orientation is not a freely selectable parameter here but implemented along a specified, uniform direction.

The shape of the apertures 351 is fixed in all of the monolithic multi-aperture plate 350 depicted in FIGS. 2A-2C. Only one (true) parameter is varied in the field of the apertures, specifically the aperture size. The present disclosure breaks loose from defining the aperture shapes in order to obtain more free parameters for the aberration corrections, even if only a single correction voltage is applied to a respective monolithic multi-aperture plate 350, as previously. According to the disclosure, it is not only the size of the aperture 351 in a plate 350 that is varied in the context of designing a monolithic multi-aperture plate or path trajectory correction plate 350 but also the respective shape of the apertures 351. Thus, within the scope of the design process, there are at least two free parameters for each aperture 351 in the monolithic multi-aperture plate 350 and not only a single parameter.

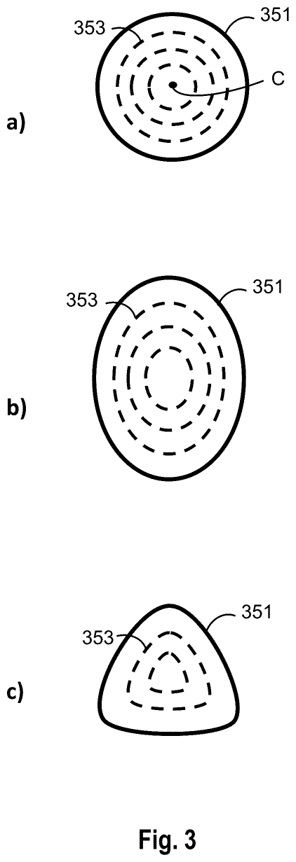

FIGS. 3A-3C schematically illustrate apertures 351 in different shapes. The outer edge of an aperture 351 is depicted in each case; it is at DC potential as a result of the application of a voltage to the multi-aperture plate 350. Additionally, dashed lines are used to depict equipotential lines 353 of the electrostatic field in the interior of the apertures 351 in a suitable sectional plane perpendicular to the particle beam.

Specifically, FIG. 3A shows a circular aperture 351 with circular equipotential lines 353 which form a circular perpendicular to the field lines. If an individual particle beam 3 passes centrally through the aperture 351, the particle beam 3 experiences a lens effect. If the passage is off axis, a deflection through a certain angle is added to the lens effect.

The aperture 351 depicted in FIG. 3B is elliptical. The equipotential lines 353 are also elliptical and perpendicular to the field lines. An astigmatism can be generated or corrected in this way.

FIG. 3C shows an aperture 351 whose shape corresponds to a rounded-off triangle, for example a rounded-off equilateral triangle. The equipotential lines 353 have the same shape. When an individual particle beam 3 passes through the aperture with 3-fold symmetry, it is for example possible to generate a trefoil of the individual particle beam profile or correct a trefoil present.

In general, an aperture 351 can have any shape provided the latter is suitable for correcting aberrations that arise.

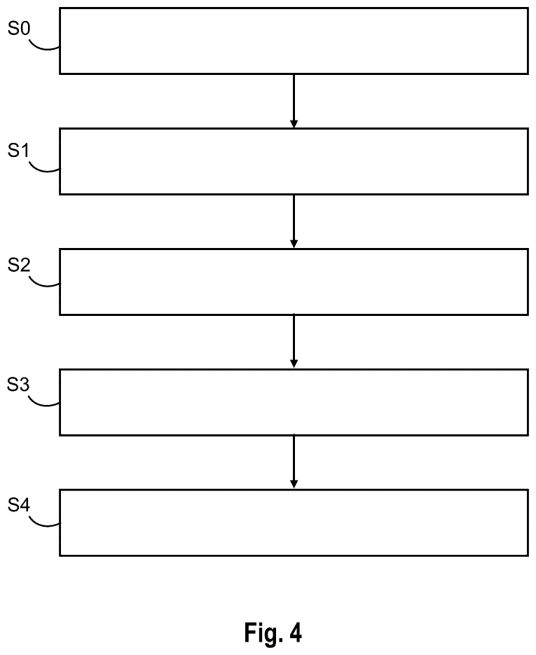

FIG. 4 illustrates, in the form of a flowchart, an example of a method according to the disclosure for designing a multi-beam particle beam system, for example a multi-beam particle microscope 1. The multi-beam particle beam system, for example the multi-beam particle microscope 1, is provided in a first method step S0. In this respect, it may actually be provided in physical form, which is to say it has already been produced. However, it is also possible that the multi-beam particle beam system 1 exists only as a simulation. The multi-beam particle beam system or multi-beam particle microscope 1 operates with a multiplicity of individual charged particle beams 3 and images these into an object plane 101. For aberration correction purposes, the multi-beam particle beam system 1 comprises a plurality of path trajectory correction plates 350, wherein each of the path trajectory correction plates 350 has a multiplicity of apertures 351 for the multiplicity of individual particle beams 3 and wherein exactly one settable correction voltage for generating a contribution to the path correction is applied to each of the path trajectory correction plates 350 during the operation of the multi-beam particle beam system 1. In this case, the number of apertures 351 per path trajectory correction plate 350 is matched to the number of individual particle beams 3 of the multi-beam particle beam system 1 to be designed, i.e. each individual particle beam 3 passes through an aperture 351 assigned thereto and only assigned thereto.

Operating parameters describing an operating state of the multi-beam particle beam system 1 are defined in a further method step S1. For example, operating parameters whose change cause an influence on the path deviations of the individual particle beams 3 from the ideal particle beam paths are selected in the process. For example, the operating parameters could be the beam current, the landing energy and the beam pitch of the individual particle beams. However, it is also possible that the operating parameters comprise such parameters or consist of such parameters which are component-related manipulation parameters. For example, such parameters can be a beam splitter excitation, an objective lens excitation, a field lens excitation, etc.

In method step S2, operating parameter intervals are defined for each operating parameter, included in which are possible values for the respective operating parameter during an operation of the multi-beam particle beam system 1. Thus, for example, the interval in which the beam current or a landing energy can be varied is defined. Defining these operating parameter intervals serves to define the phase space of the multi-beam particle beam system 1 where aberrations should be corrected at all. In this case, the aberrations are dependent on the operating parameters.

In a method step S3, there is a determination of an individual particle beam path deviation from an ideal individual particle beam path for each operating parameter along its operating parameter interval for each of the individual particle beams 3. By way of example, this path deviation can be determined by an appropriate particle-optical simulation. However, it is also possible that corresponding measurements are taken at the already existing multi-beam particle beam system 1. By way of example, the beam profile is measured in the object plane and/or the position and shape of the minimal beam waist can be measured. Subsequently, the path trajectory correction plates 350 yet to be designed are added to or implemented in the system.

Then, the path trajectory correction plates 350 are designed in method step S4. According to the disclosure, each operating parameter is assigned a path trajectory correction plate 350. The sizes of the apertures 351 are determined for each path trajectory correction plate 350 on the basis of the respective determined path deviations of the associated individual particle beams 3 along the operating parameter interval. Moreover, the shapes of the respective apertures 351 are determined for each path trajectory correction plate 350 on the basis of the respective determined path deviations of the associated individual particle beams 3 along the operating parameter interval. In this case, determining the sizes and the shapes of the respective apertures can be implemented in two separate method steps or else in a combined method step. In general, this depends on the type of mathematical implementation of the design method. However, what is decisive in any case is that at least two free parameters, for example the shape and the size, are selected or optimized for each aperture during this design process for the multi-aperture plates 350. The nature of an aperture with a specific shape and size then is such that a path correction is as optimal as possible for each value of the operating parameter to which a specific correction voltage is assigned.

Attention is once again drawn to the fact that there is as it were a type of basis change according to the disclosure: Rather than providing an individual multi-aperture plate or a sequence of multi-aperture plates for correcting a specific category or type of imaging aberration (field curvature or astigmatism correction or image plane tilt, etc.), the monolithic multi-aperture plates or path trajectory correction plates 350 are designed according to the disclosure for the purpose of a tailored correction of imaging aberrations to changes in specific operating parameters. At this juncture, explicit reference is once again made to the corresponding explanations in the general part of the description of the disclosure.

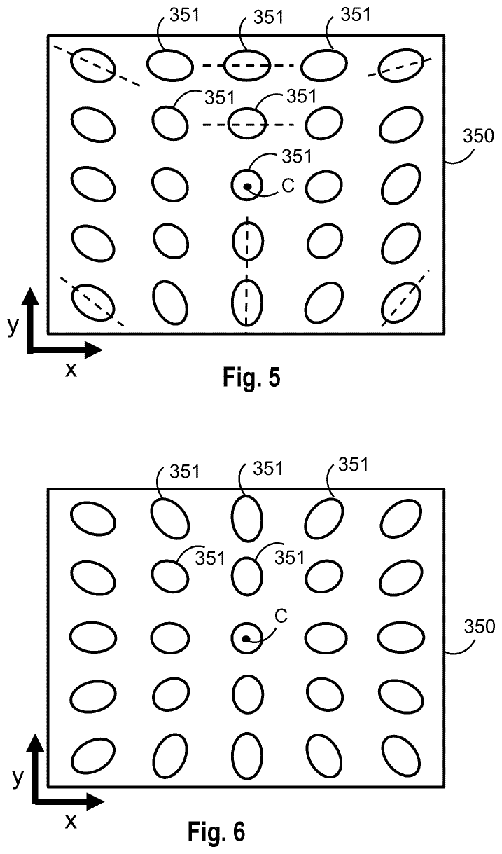

FIG. 5 schematically shows a path trajectory correction plate 350 for a beam splitter 400. The apertures 351 were varied in terms of shape and size when designing this path trajectory correction plate 350. The result is a path trajectory correction plate 350 with apertures of varying ellipticity 351; in this case, the apertures may also be non-elliptical from a strict mathematical point of view. A field profile of the apertures 351 can be identified in FIG. 5. A central aperture 351 around the midpoint C is circular and comparatively small, the remaining apertures 351 tend to be larger. If a longitudinal axis is plotted into the oval shapes of the apertures 351, then very different orientations of these longitudinal axes are evident. The orientation of these axes alone is already a significant difference to the already known uniform orientation of longitudinal axes for a pure astigmatism correction (cf. FIG. 2C).

FIG. 6 schematically shows a path trajectory correction plate 350 for a magnetic objective lens 102. Both the size and the shape of the aperture 351 were freely selectable or optimizable when designing this path trajectory correction plate 350, too. In the depicted example, the apertures 351 are substantially elliptical; this can be traced back to the fact that the objective lens 102 inter alia causes a field astigmatism as an aberration when its manipulation parameter or its excitation is modified. However, this could also be different.

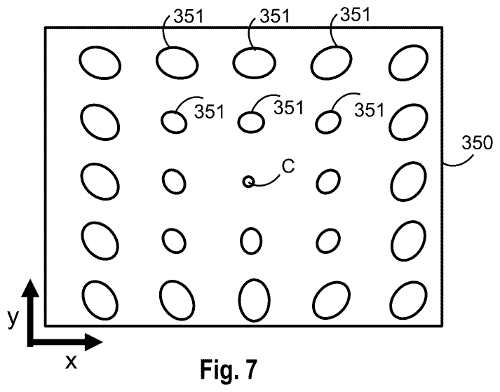

FIG. 7 shows a path trajectory correction plate 350 for an objective lens 102 which causes two leading aberrations, specifically a field curvature and a field astigmatism, in the case of a change in excitation. The multi-aperture plate 350 designed in accordance with the method according to the disclosure substantially comprises elliptical apertures 351 which, in general, correspond to a superimposition of ellipses and circular apertures 351. This example vividly shows that it is not mandatory to correct each category of imaging aberration with a separate monolithic multi-aperture plate and consequently use a plurality of correction plates overall. Instead, it is also possible to obtain a complete aberration correction when changing a certain manipulation parameter, in this case the excitation of an objective lens 102, by virtue of the apertures 351 in a single path trajectory correction plate 350 being designed accordingly. In the case of such a procedure, the shapes of the apertures are not fixedly specified but can be variably defined during the design of the path trajectory correction plate 350.

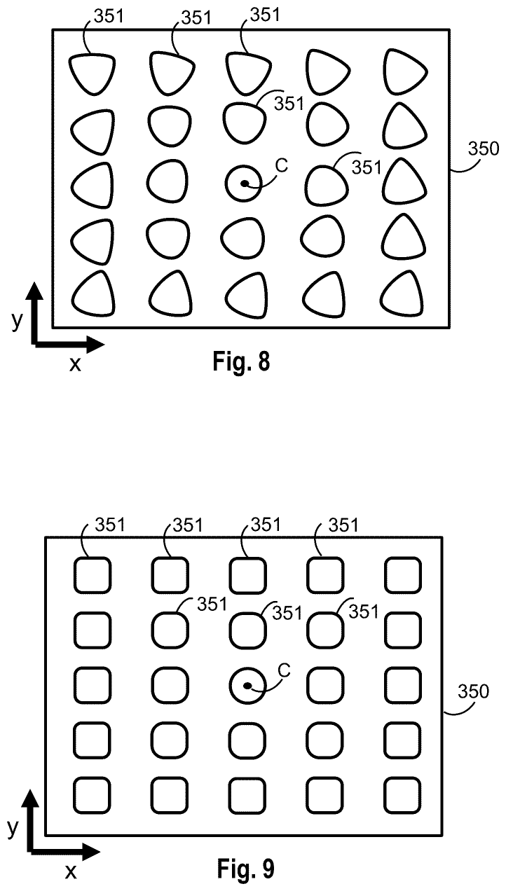

FIG. 8 schematically shows a path trajectory correction plate 350 with three-fold apertures of different shapes. By way of example, various three-fold shapes can generate hexapoles or correct hexapole components in aberrations. Here, too, the alignment and hexapole intensity vary with position.

FIG. 9 schematically shows a path trajectory correction plate 350 with four-fold apertures 351 of different shapes. Generally, these shapes are squares that are rounded off to greater or lesser extent. Such apertures 351 can generate octupoles when a voltage is applied to the path trajectory correction plate 350 and can correct components of four-fold aberrations.

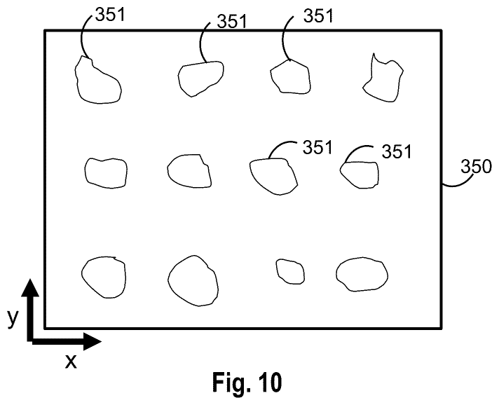

FIG. 10 schematically shows a path trajectory correction plate 350 with free-form apertures 351. This example of a path trajectory correction plate 350 is the logical consequence of a completely free optimization of the shapes of apertures 351. In theory, it is possible for an aperture 351 to be formed in any shape; what is decisive is that the aperture 351 is in fact suitable for correcting path deviations of the individual particle beam 3 passing therethrough. This correction is implemented not only for a specific value of an operating parameter but along the entire operating parameter interval (point by point or continuously). In this case, the value of the respective operating parameter is always assigned a correction voltage applied to the monolithic multi-aperture plate 350.

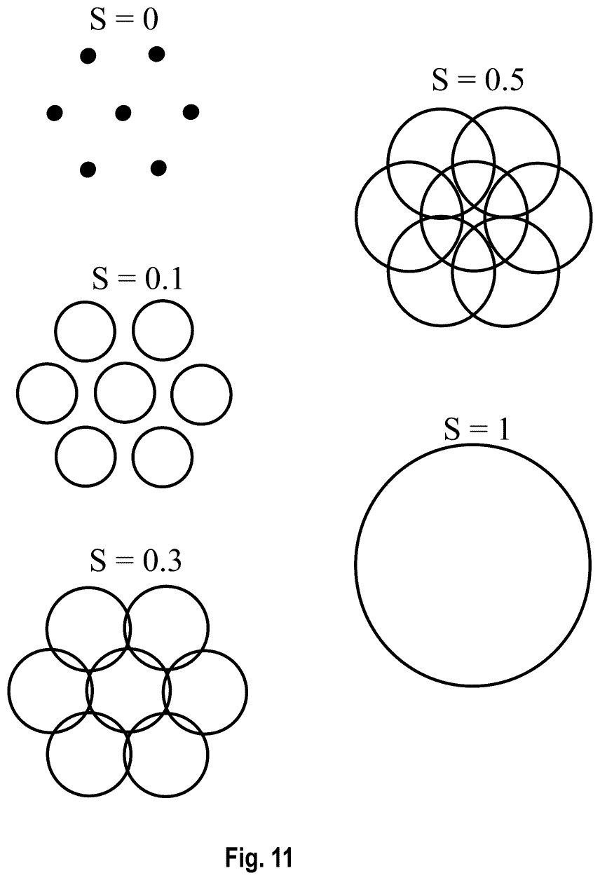

FIG. 11 schematically illustrates the ratio S of individual beam diameter to beam bundle diameter. Inter alia, this ratio provides information as to whether the multiplicity of individual particle beams in the particle-optical beam path are strictly separated from one another or else whether the individual particle beams 3 overlap one another. This is decisive for whether an individual path trajectory correction can be carried out for each individual particle beam 3 or whether it is only still possible to carry out a global path trajectory correction jointly for all individual particle beams 3. However, even the latter case still allows for at least a weak field-dependent change in the individual particle beams to be implemented via a global lens or global electrode. However, in practice, an aberration to be corrected by a global path trajectory correction will be at least substantially field independent.

In the case of a ratio of S=0, the diameter of each individual particle beam 3 is very much smaller than the beam diameter of the entire bundle, illustrated in FIG. 11 as a hexagonal arrangement of seven individual particle beams 3. In a multi-beam particle beam system 1, the ratio S=0 is realized in an intermediate image position. Thus, the individual particle beams 3 are very clearly separated from one another, with the result that an individual beam correction or path trajectory correction can be implemented at this position. Thus, for example, a path trajectory correction plate with a multiplicity of apertures for each of the individual particle beams 3 can be arranged at such a location. However, exactly at the intermediate image position, it is only the angle of each individual particle beam 3 and not the position of the individual particle beams 3 that can be influenced via the path trajectory correction plate 350, to which a predefined correction voltage has been applied. Thus, for example, a telecentricity path trajectory correction plate 350 can be arranged in the intermediate image.

In the case of a ratio of S=0.1 of individual beam diameter to beam bundle diameter, the first individual particle beams 3 are still strictly separated from one another; the diameter of each individual particle beam 3 is expanded. For example, this situation is present in the region of the multi-beam particle generator 305 of a multi-beam particle beam system 1 or multi-beam particle microscope 1. Thus, for example, a path trajectory correction plate 350 can be integrated in the multi-beam particle generator 305. In general, any field dependence of aberrations can be corrected individually for each individual particle beam 3 using a path trajectory correction plate 350 at a position satisfying S=0.1.

The individual particle beams 3 are no longer strictly separated from one another in the case of a ratio of S=0.3 of individual beam diameter to beam bundle diameter, which is why a path trajectory correction plate 350 with individual apertures for each individual particle beam can no longer be meaningfully arranged at such a position in the particle-optical beam path. For example, there is a relationship of S=0.3 near an image field plane.

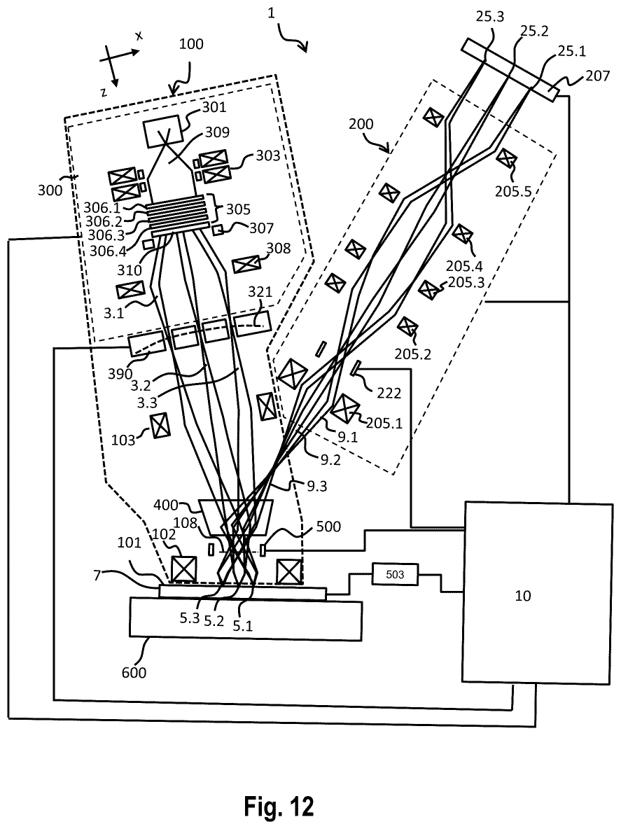

FIG. 12 schematically shows a multi-beam particle microscope 1 with path trajectory correction plates, designed in accordance with the method according to the disclosure. In the example shown, path trajectory correction plates are integrated in the multi-beam particle generator 305. The multi-beam particle generator 305 has a multiplicity of multi-aperture plates. These can serve firstly for generating the multiplicity of individual particle beams 3 and for the first beam shaping. In addition or in an alternative, the path trajectory correction plates 350 according to the present disclosure may be arranged in the multi-beam generator 305.

By way of example, FIG. 12 depicts a multiplicity of multi-aperture plates 306.1, 306.2, 306.3 and 306.4. However, the multi-beam particle generator 305 may naturally also comprise even more multi-aperture plates. In the example shown, at least two of the multi-aperture plates 306.1 to 306.4 are path trajectory correction plates 350 according to the present disclosure, the multiplicity of apertures 351 of which are passed during operation by the multiplicity of first individual particle beams 3 and to which exactly one correction voltage assigned to the path trajectory correction plate 350 is applied during operation. Apertures 351 of different sizes and different shapes are arranged in at least one path trajectory correction plate or these apertures 351 have been optimized or determined by at least two free parameters, for example corresponding to a size and a shape, within the scope of the design process for the multi-beam particle microscope 1. The path trajectory correction plates 350 are controlled individually during operation by the controller 10 with a correction voltage which has been individually predefined for the respective path trajectory correction plate 350, wherein the respective correction voltage is selected by the controller 10 on the basis of the respective value of the operating parameter for the multi-beam particle microscope 1.

For example, it is possible that one of the path trajectory correction plates, for example the path trajectory correction plate 306.4, is adapted to undertake a path trajectory correction on the basis of a beam current or a beam current change. In addition or in an alternative, it is possible that for example the path trajectory correction plates 306.3 is adapted to undertake a path trajectory correction on the basis of a landing energy or a change in the landing energy. In addition or in an alternative, it is for example possible that the path trajectory correction plate 306.2 is adapted to undertake a path trajectory correction on the basis of a pitch or a change in pitch of the first individual particle beams upon incidence of the first individual particle beams 3 in the object plane 101 (change in pitch).

In addition or in an alternative, the multi-beam generator 305 may comprise one or more further path trajectory correction plates 350. For example, it is possible to provide a path trajectory correction plate 350 in order to undertake a path trajectory correction on the basis of an excitation or an excitation change of the objective lens 102. In addition or in an alternative, one of the path trajectory correction plates 350 can be adapted to undertake a path trajectory correction on the basis of an excitation or an excitation change of the beam splitter 400. In addition or in an alternative, one of the path trajectory correction plates can be adapted to undertake a path trajectory correction on the basis of an excitation or an excitation change of a field lens arranged in the first particle-optical beam path 13. For example, this field lens can be one of the field lenses 307, 308 or 103. The shape of the apertures in the path trajectory correction plates 350 can also be a useful combination of the aforementioned shapes and shape profiles which for example minimizes the number of correction plates 350 involved.

According to an example, a respective multi-aperture plate with a multiplicity of round apertures is arranged directly upstream and directly downstream of a path trajectory correction plate 350, wherein the same voltage, for example earth potential, is applied to the two multi-aperture plates. An individual lens or a system of a plurality of individual lenses can be realized in this way. The provision of the two multi-aperture plates, especially the two earthed multi-aperture plates, even between two path trajectory correction plates contributes to separating the fields or field profiles caused by the path trajectory correction plates from one another.

According to an exemplary embodiment of the disclosure, the multi-beam particle microscope 1 comprises a voltage source 503 which is configured to implement a landing energy of the first individual particle beams 3 by changing the deceleration field near a sample surface or wafer surface, which is arranged in the object plane 101. The modified landing energy also changes the focal position of the first individual particle beams 3 upon incidence on the object plane 101. This can be corrected in a targeted fashion via a path trajectory correction plate 350, which is designed exactly for a landing energy correction. The apertures 351 best suited to this end can be designed ideally in terms of size and shape. In many cases, such a landing energy correction plate has comparatively round apertures, the diameters of which varies linearly with the distance from the central beam or a plate centre.

In addition or in an alternative, it is possible that a spherical component of a path trajectory is corrected, for example caused by a change in the refractive power of any lens in the first particle-optical beam path. In turn, this lens can be assigned a specific lens correction plate 350 for correcting the path trajectory. Here, too, it is possible to design the apertures 351 of this lens correction plate 350 optimally for the specific multi-beam particle microscope 1 and, for example, not only specify a quadratic dependence of aperture diameters for the lens correction plate. Naturally, however, this may be the case in general.

In the example shown in FIG. 12, a path trajectory correction plate 390 is moreover provided in the region of the intermediate image or along the curved intermediate image plane 321 and it can undertake a path trajectory correction on the basis of an angle or an angle change of the first individual particle beams 3 upon incidence of the first individual particle beams 3 in the object plane 101. Thus, for example, the path trajectory correction plate 390 is the aforementioned telecentricity correction plate 390. Its voltage supply is controlled in turn by the controller 10, to be precise on the basis of the selected operating parameter, in this case the telecentricity or the angle.

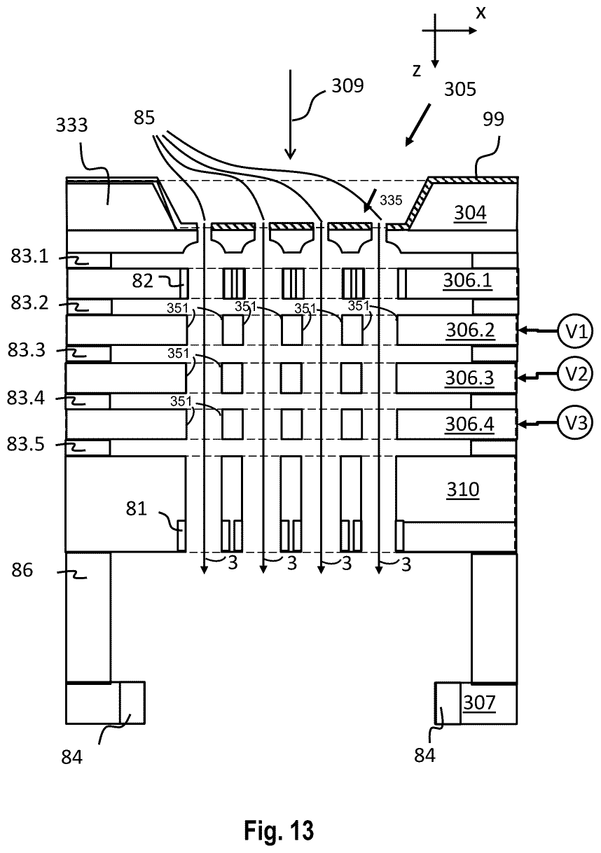

FIG. 13 schematically shows a multi-beam generator 305 with monolithic path trajectory correction plates 306.2, 306.3 and 306.4. Voltages V1, V2 and V3 are applied to these path trajectory correction plates 306.2, 306.3 and 306.4, respectively. The value of these correction voltages V1, V2, V3 depends on the operating parameters and their current values assigned to the respective path trajectory correction plates 306.2, 306.3 and 306.4. The operating parameters and the associated correction voltages V1, V2, V3 are provided or set by the controller 10 of the multi-beam particle microscope 1.

FIG. 13 further shows for example the integration of the path trajectory correction plates 306.2, 306.3 and 306.4 according to the disclosure in already existing multi-beam generators 305. In the illustrated example, the multi-beam generator 305 comprises a sequence with six multi-aperture plates 304, 306.1, 306.2, 306.3, 306.4 and 310 and a global condenser lens 307 in the z-direction, which corresponds to the direction of propagation of the individual particle beams 3. Each of the multi-aperture plates 304, 306.1 to 306.4 and 310 comprises a multiplicity of apertures 351, which are passed by the multiplicity of individual particle beams 3 in each case. The cross section through the apertures 351 in FIG. 13 is not true to scale; instead, the illustration in FIG. 13 emphasizes the fundamentally possible arrangement of path trajectory correction plates 350 in the form of the multi-aperture plates 306.2, 306.3 and 306.4 in a multi-beam generator 305.

The multiplicity of multi-aperture plates 304, 306.1, 306.2, 306.3, 306.4 and 310 are spaced apart from one another by spacers 83.1 to 83.5. Moreover, a spacer 86 is provided between the final multi-aperture plate 310 and the global lens electrode 307. As a result of the incidence of a collimated particle or electron beam 309, the multiplicity of first individual particle beams 3 are generated during the passage through the first multi-aperture plate 304, which is also referred to as filter plate or pre-aperture plate. The pre-aperture plate 304 comprises a metallic layer 99 on its beam input side, for stopping and absorbing the electrons of the electron beam 309 incident thereon around the multiplicity of the apertures 85. In this case, the material of the pre-aperture plate 304 is produced from a conductive material in the example shown, for example doped silicon, and is at earth potential.

In the example shown in FIG. 13, the next multi-aperture plate is a multi-stigmator plate 306.1. The multi-stigmator plate 306.1 comprises a multiplicity of four or more electrodes 82, for example eight electrodes for each aperture. Different voltages, for example ranging between −20 V and +20 V, can be applied to each of these electrodes during the operation of the multi-beam particle microscope 1 and hence individually influence each individual particle beam 3. For example, it is possible with an antisymmetric voltage difference to deflect each individual particle beam 3 up to a few μm in each direction in order to pre-correct a distortion correction of the unit 100 to be illuminated. An astigmatism pre-correction for each individual particle beam 3 can be undertaken in this way. Via an offset voltage, each multi-pole element can additionally act as an individual lens.

In general, the multi-aperture plates 306.2, 306.3 and 306.4 which implement path trajectory correction plates 350 in the illustrated example can be any type of path trajectory correction plates 350. By way of example, the path trajectory correction plate 306.2 could correspond to a landing energy correction plate, the multi-aperture plates 306.3 could correspond to a beam current correction plate and the multi-aperture plate 306.4 could correspond to a distance correction plate or pitch correction plate. However, it is also possible that even more path trajectory correction plates 350 could also be provided. Alternatively, the multi-aperture plates 306.2, 306.3 and 306.4 could be an objective lens correction plate, a beam splitter correction plate and a field lens correction plate, for example. Otherwise, what was already stated in the general part of the description of the disclosure is also applicable.

The multi-aperture plate 310 is a two-layer multi-aperture plate and comprises a multiplicity of ring electrodes 79 for the multiplicity of apertures, wherein each ring electrode is configured to individually change or modify a focal position of the first individual particle beam 3 passing therethrough. In this case, the upper layer is insulated from the layer or ply with the ring electrodes 79 and produced from a conductive material such as doped silicon, for example.

The field lens 307 comprises a ring electrode 84, to which a high voltage of for example 3 kV to 20 kV can be applied, for example 12 kV to 17 kV. In the example shown, the condenser lens 307 provides a global electrostatic lens field for global focusing of the multiplicity of individual particle beams 3.

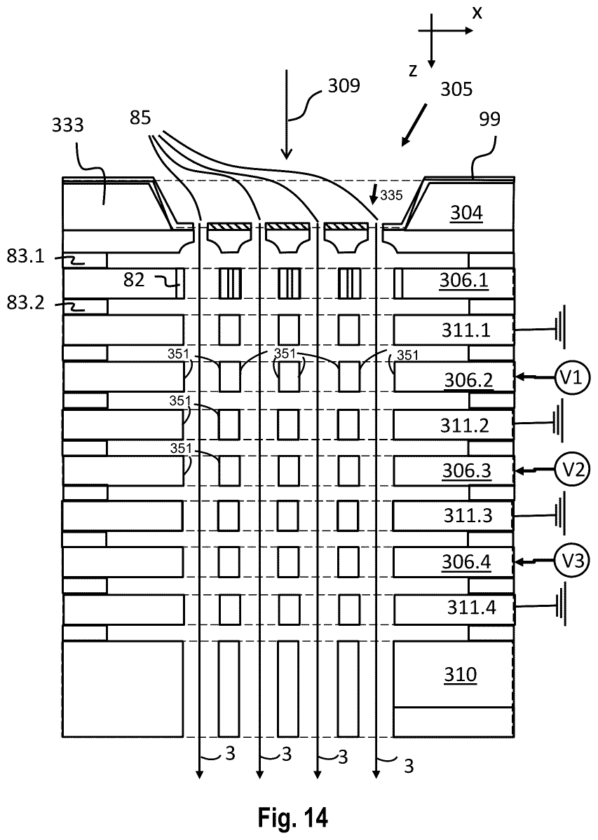

FIG. 14 schematically shows a detail of a multi-beam generator 305 with monolithic path trajectory correction plates. In contrast to FIG. 13, an earthed multi-aperture plate 311.1 to 311.4 with a multiplicity of round apertures 351 is now provided between the path trajectory correction plates 306.2, 306.3 and 306.4 and in each case directly upstream or directly downstream thereof. This facilitates the separation of the individual corrections or correction fields from one another. Naturally, other integrations or arrangements in the multi-beam generator 305, both in view of the number and in view of the sequence of multi-aperture plates are possible.

According to a further embodiment of the disclosure, the multi-beam particle microscope 1 moreover comprises a mechanism for in-situ plasma cleaning of the path trajectory correction plates 350; and/or the multi-beam particle microscope 1 comprises a mechanism for providing a low partial pressure of hydrogen gas during an operation of the multi-beam particle microscope 1 for cleaning purposes. The hydrogen can be provided continuously during the operation of the multi-beam particle microscope 1 or it can be provided in pulsed form or intermittently between various recordings or, in general terms, during an interruption of an image recording—or interruption of a scanning procedure. The mechanism for in-situ plasma cleaning and/or the mechanism for providing hydrogen can in this case be arranged in the region of the multi-beam generator 305 (not explicitly depicted in FIGS. 13 and 14). In addition or in an alternative, the multi-beam particle microscope 1 may comprise a mechanism for continually heating the path trajectory correction plates 350. Heating contributes to the cleaning of the path trajectory correction plates 350. Cleaning the path trajectory correction plates 350 is desirable for a correct functionality of the path trajectory correction plates or for a precise correction of the path trajectories since contaminations or deposits on the apertures 351 in the path trajectory correction plates 350 may impair the highly precise correction. For example, it is possible to heat the path trajectory correction plates 306.2, 306.3 and 306.4 which are depicted in FIGS. 13 and 14 (the heating mechanism is not explicitly depicted in FIGS. 13 and 14). Moreover, it is also possible to heat the earthed multi-aperture plates 311.1 to 311.4, which are provided with a multiplicity of round apertures 351, or else other multi-aperture plates of the multi-beam generator.

Overall, it should be noted that, according to the present disclosure, a very comprehensive, precise and tailored path trajectory correction can be implemented for the multiplicity of individual particle beams 3 using a very small number of path trajectory correction plates 350. These path trajectory corrections can also be applied analogously to the secondary beam path.

The following are disclosed: a method for designing a multi-beam particle microscope 1 and a multi-beam particle microscope 1 operating with a multiplicity of charged individual particle beams 3 and imaging the latter into an object plane 101 and comprising a plurality of path trajectory correction plates 350. Each of the path trajectory correction plates 350 has a multiplicity of apertures 351 for the multiplicity of individual particle beams 3 and exactly one settable correction voltage is applied to each of the path trajectory correction plates 350 during the operation of the multi-beam particle microscope 1. A path trajectory correction plate 350 is fixedly assigned to an operating parameter of the multi-beam particle microscope 1. When designing the path trajectory correction plates, the apertures 351 in the path trajectory correction plates 350 are adapted in view of shape and size such that operating parameter-related path deviations of all individual particle beams 3 can be corrected.

### LIST OF REFERENCE SIGNS

1 Multi-beam particle microscope
3 Primary particle beams, first individual particle beams
5 Beam spots, incidence locations
7 Object, sample, wafer
9 Secondary particle beams, second individual particle beams
10 Computer system, controller
15 Sample surface, wafer surface
25 Image point of a second individual particle beam
81 Multi-pole electrode
82 Ring electrode
83 Spacer
84 Ring electrode
85 Aperture
86 Spacer
99 Absorbing and conducting layer
101 Object plane
102 Objective lens
103 Field lens
105 Axis
108 Pupil plane
200 Detector system
205 Projection lens system
206 Projection lens
207 Multi-particle detector
208 Projection lens
209 Projection lens
210 Projection lens
212 Cross-over
214 Aperture filter, contrast stop
220 Multi-aperture corrector, individual deflector array
222 Collective anti-deflection system
300 Beam generating apparatus
301 Particle source
303 Collimation lens system
304 Multi-aperture array, filter plate
305 Multi-aperture arrangement, multi-beam particle generator
306 Micro-optics with multi-aperture plates
307 Field lens
308 Field lens
309 Diverging particle beam
310 Multi-aperture plate
311 Earthed multi-aperture plate with round apertures
321 Intermediate image plane
323 Beam foci
333 Holding region
335 Membrane region
350 Monolithic multi-aperture plate, path trajectory correction plate
351 Aperture
390 Telecentricity correction plate
400 Beam splitter, magnet arrangement
500 Scan deflector
503 Voltage source
600 Displacement stage or positioning device
701 Global path trajectory corrector (near pupil)
703 Global path trajectory corrector (between field and pupil)
A Axis
C Centre
r Radial direction
x Direction
y Direction
z Direction
l Longitudinal axis
S Ratio of individual beam diameter to beam bundle diameter

1. A method of designing a multi-beam particle beam system configured to image a multiplicity of charged individual particle beams into an object plane, the multi-beam particle system comprising a multiplicity of path trajectory correction plates, each path trajectory correction plate comprising a multiplicity of apertures for the multiplicity of individual particle beams, the multi-beam particle system configured so that during operation exactly one settable correction voltage to generate a contribution to the path correction is applied to each path trajectory correction plates, the method comprising:
defining operating parameters which describe an operating state of the multi-beam particle beam system;
defining operating parameter intervals for each operating parameter, the operating parameter intervals comprising possible values for a respective operating parameter during an operation of the multi-beam particle beam system;
determining an individual particle beam path deviation from an ideal individual particle beam path for each operating parameter along its operating parameter interval for each of the individual particle beams; and
designing the path trajectory correction plates,
wherein:
each operating parameter is assigned a path trajectory correction plate;
sizes of the apertures are determined for each path trajectory correction plate based on the respective determined path deviations of the associated individual particle beams along the operating parameter interval;
shapes of the respective apertures are determined for each path trajectory correction plate based on the respective determined path deviations of the associated individual particle beams along the operating parameter interval; and
path deviations occurring due changes of an operating parameter within its operating parameter interval are correctable by applying exactly one correction voltage to the path trajectory correction plate assigned to this operating parameter.

2. The method of claim 1, wherein the respective path deviations of the individual particle beams are determined upon incidence in an object plane.

3. The method of claim 1, wherein the orientation of the shape within the path trajectory correction plate is also determined when determining the shape of an aperture.

4. The method of claim 1, wherein:
determining the size of a respective aperture via a simulation includes a determination of a relationship between the size of the respective aperture and a focus shift caused thereby when a correction voltage is applied to the path trajectory correction plate; and/or
determining the shape of a respective aperture via a simulation includes the determination of a relationship between the shape of the respective aperture and a modified beam profile caused thereby when a correction voltage is applied to the path trajectory correction plate.

5. The method of claim 4, wherein the method comprises a repeat determination of a relationship between:
the size of the aperture and a focus shift caused thereby when at least one further correction voltage is applied; and/or
the shape of the aperture and a modified beam profile caused thereby when at least one further correction voltage is applied.

6. The method of claim 1, wherein:
the correction voltages applied to a path trajectory correction plate cover or correct path deviations substantially over the entire operating parameter interval of the path trajectory correction plate associated with this operating parameter; and
the following are determined: a best fit at all applied correction voltages for the size of the aperture; and a best fit for the shape of the aperture for the individual particle beam passing through this aperture.

7. The method of claim 1, wherein designing a path trajectory correction plate comprises optimizing the individual particle beam profiles to a most astigmatic beam profile possible downstream of the path trajectory correction.

8. The method of claim 1, wherein at least one aperture in a path trajectory correction plate has the shape of at least one shape selected from the group consisting of a circle, an ellipse, a shape with a two-fold symmetry, a shape with a three-fold symmetry, a shape with a four-fold symmetry, a shape with a five-fold symmetry, a shape with a six-fold symmetry, a shape with a seven-fold symmetry, and a shape with an eight-fold symmetry.

9. The method of claim 1, wherein at least one aperture in a path trajectory correction plate has a free-form shape.

10. The method of claim 1, wherein the operating parameters are selectable.

11. The method of claim 1, wherein the operating parameters comprise at least one parameter selected from the group consisting of a beam current, a landing energy, a pitch of the individual particle beams upon incidence in an object plane, and an angle upon incidence of the individual particle beams in an object plane.

12. The method of claim 1, wherein the operating parameters comprise component-related manipulation parameters.

13. The method of claim 12, wherein the manipulation parameters comprise at least one member selected from the group consisting of a beam splitter excitation, an objective lens excitation, and a field lens excitation.

14. The method of claim 1, wherein an operating parameter is assigned exactly one path trajectory correction plate.

15. The method of claim 1, further comprising minimizing the number of path trajectory correction plates in the multi-beam particle system.

16. The method of claim 1, wherein a number of all operating parameters of the multi-beam particle beam system is greater than a number of all path trajectory correction plates in the system.

17. The method of claim 1, further comprising selecting a base set of path trajectory correction plates which provide a path trajectory correction for all path corrections to be expected in the system to be designed.

18. The method of claim 1, wherein the multi-beam particle beam system comprises a multi-beam particle microscope.

19. One or more machine-readable hardware storage devices comprising instructions that are executable by one or more processing devices to perform operations comprising the method of claim 1.

20. A system comprising:
one or more processing devices; and
one or more machine-readable hardware storage devices comprising instructions that are executable by the one or more processing devices to perform operations comprising the method of claim 1.

21. The system of claim 20, wherein the system comprises a multi-beam particle microscope.

22. A multi-beam particle microscope, comprising:
a multi-beam generator configured to generate a first field of a multiplicity of charged first individual particle beams;
a first particle-optical unit having a first particle-optical beam path, the first particle-optical unit configured to image the first individual particle beams onto a sample surface in the object plane so that the first individual particle beams are incident on the sample surface at incidence locations defining a second field;
a detection system comprising a multiplicity of detection regions defining a third field;
a second particle-optical unit with a second particle-optical beam path, the second particle-optical unit configured to image second individual particle beams emanating from the incidence locations in the second field onto the third field of the detection regions of the detection system;
a magnetic and/or electrostatic objective lens configured so that both the first and the second individual particle beams pass through the magnetic and/or electrostatic objective lens;
a beam splitter disposed in the first particle-optical beam path between the multi-beam generator and the objective lens, the beam splitter disposed in the second particle-optical beam path between the objective lens and the detection system;
a plurality of path trajectory correction plates; and
a controller,
wherein:
each path trajectory correction plate comprises a multiplicity of apertures configured so that, during operation of the multi-beam particle microscope, the multiplicity of first individual particle beams passes therethrough;
each path trajectory correction plane is configured so that, during operation of the multi-beam particle microscope, exactly one correction voltage assigned thereto;
apertures of different sizes and different shapes are present in at least one of the path trajectory correction plates;
the controller is configured so that, during operation of the multi-beam particle microscope, the controller controls the plurality of path trajectory correction plates via a correction voltage which is individually predefined for each path trajectory correction plate, each correction voltage selected by the controller based on operating parameters for the multi-beam particle microscope.

23.-29. (canceled)
